(19) United States
(12) Patent Application Publication
(10) Pub. No.: US 2022/0140748 A1
(43) Pub. Date: May 5, 2022

(54) SEMICONDUCTOR DEVICE AND INVERTER DEVICE

(71) Applicant: RENESAS ELECTRONICS CORPORATION, Tokyo (JP)

(72) Inventors: Tetsu TODA, Tokyo (JP); Tatsuo HARADA, Tokyo (JP); Daisuke IIJIMA, Tokyo (JP); Syuuichi KIKUCHI, Tokyo (JP); Kotaro KURODA, Tokyo (JP)

(21) Appl. No.: 17/090,491

(22) Filed: Nov. 5, 2020

(51) Int. Cl. H02M 7/5387; H01L 27/06

(52) U.S. Cl. CPC H02M 7/5387; H01L 27/0629

(57) ABSTRACT

An inverter device includes first and second input terminals, a series circuit having a plurality of switch elements coupled between the first and second input terminals. Each of the switch elements is coupled in parallel with a series circuit having a diode and an inductor.

### BACKGROUND

The present invention relates to a semiconductor device, for example, to a semiconductor device which can be suitably utilized for the inverter device used in motor control.

A full-bridge inverter device is known as an inverter device that converts single DC power into AC power. The inverter device converts direct current into alternating current and controls the motor and is used in a wide range of fields such as in-vehicle, industrial and consumer fields. Japanese Unexamined Patent Application Publication No. 2016-146386 (Patent Document 1) discloses a technique for suppressing ringing of switching waveforms in a full-bridge inverter circuit.

### SUMMARY

The full-bridge inverter circuit includes four switch elements, as shown in FIG. 1 of Patent Document 1. The full-bridge inverter circuit alternately conducts switch elements arranged diagonally, and controls the width of the ON pulse to a variable, to control the output voltage. By using the full-bridge inverter circuit, the power supply device can be made smaller and lighter, and noise reduction and power conversion efficiency can be improved. However, the switch elements are not switched instantaneously. Therefore, power loss in the switching time (hereinafter, referred to as switching loss) occurs.

The switching loss is obtained by (power loss generated per pulse)*(switching frequency). The switching loss increases in proportion to the switching frequency. In recent years, since the switching frequency tends to increase, the switching loss also tends to increase. Therefore, in order to prevent a decrease in power conversion efficiency while increasing the switching frequency, a reduction in switching loss generated for each pulse is required.

Other objects and novel features will become apparent from the description of this specification and the accompanying drawings.

According to an embodiment, semiconductor device includes a first input terminal and a second input terminal, a series circuit comprising a plurality of switch elements coupled between the first and second input terminals, further, a series circuit comprising a diode and an inductor and coupled in parallel to each of the plurality of switch elements.

According to the one embodiment, it is possible to reduce the switching loss of the switching elements in the inverter device.

### BRIEF DESCRIPTION OF THE DRAWINGS

FIG. 1 is a diagram showing a configuration of a typical full-bridge inverter circuit.

FIG. 2 is a diagram showing a configuration of an inverter device according to first embodiment.

FIGS. 3A to 3E are diagrams illustrating the operations of the full-bridge inverter circuit according to first embodiment.

FIG. 4 is a diagram showing a current flowing through the switch element and a voltage applied across the switch element.

FIG. 5 is a diagram showing a simulated result of switching loss according to first embodiment.

FIG. 6 is a diagram illustrating a configuration of a typical HERIC inverter device.

FIG. 7 is a diagram illustrating drive signals of the HERIC inverter device.

FIGS. 8A and 8B are diagrams illustrating the operations of the HERIC inverter device.

FIG. 9 is a diagram showing a configuration of a HERIC inverter device according to second embodiment.

FIGS. 10A and 10B are diagrams for explaining the operations of the HERIC inverter device according to second embodiment.

FIG. 11 is a diagram showing a simulated result of switching loss according to second embodiment.

### DETAILED DESCRIPTION

Hereinafter, a semiconductor device according to an embodiment will be described in detail by referring to the drawings. In the specification and the drawings, the same or corresponding form elements are denoted by the same reference numerals, and a repetitive description thereof is omitted. In the drawings, for convenience of description, the configuration may be omitted or simplified. Also, at least some of the embodiments may be arbitrarily combined with each other.

### First Embodiment

In first embodiment, the inverter device including an inverter circuit will be described. In particular, the inverter device including a full-bridge inverter circuit will be described.

### Configuration of Typical Full-Bridge Inverter Circuit

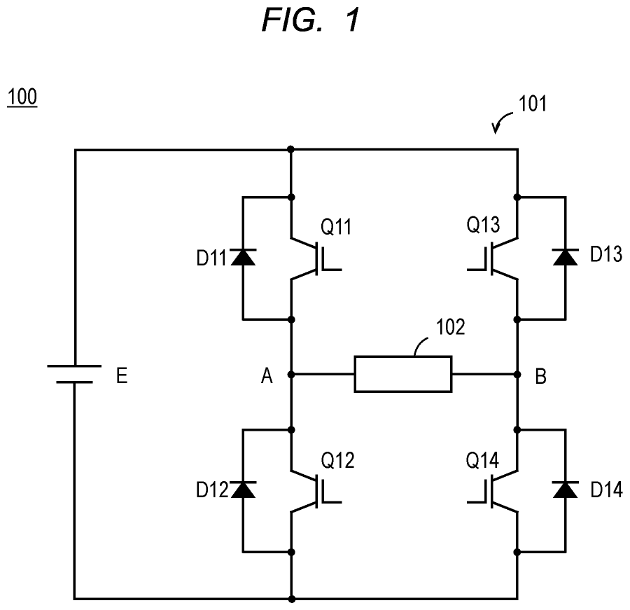

Before describing of the present embodiment, a typical full-bridge inverter device 100 will be explained with reference to FIG. 1 in order to facilitate the understanding of present embodiment. The full-bridge inverter device 100 shown in FIG. 1 includes a full-bridge inverter circuit 101. The full-bridge inverter circuit 101 is electronically coupled to the DC power source E. The full-bridge inverter circuit 101 includes switch elements Q11 to Q14 and diodes D11 to D14.

The switch element Q11 and the switch element Q12 are coupled in series. The switch element Q11 and the switch element Q12 coupled in series are coupled in parallel to the DC power source E The switch element Q11 is disposed on the high side (positive potential side), the switch element Q12 is disposed on the low side (negative potential side). A diode D11 is coupled in anti-parallel with the switch element Q11, and a diode D12 is coupled in anti-parallel with the switch element Q12.

Similarly, the switch element Q13 and the switch element Q14 are coupled in series. The switch element Q13 and the switch element Q14 coupled in series are coupled in parallel to the DC power source E. The switch element Q13 is disposed on the high side (positive potential side), and the switch element Q14 is disposed on the low side (negative potential side). A diode D13 is coupled in anti-parallel with the switch element Q13, and a diode D14 is coupled in anti-parallel with the switch element Q14.

A load 102 is electrically coupled between a node A, which is a joint of the switch element Q11 and the switch element Q12, and a node B, which is a joint of the switch element Q13 and the switch element Q14. For example, the load 102 is an inductor, hereinafter referred to as an inductor 102.

### Operation of Typical Full-Bridge Inverter Device

Next, the operation of a typical full-bridge inverter device will be described. The full-bridge inverter circuit 101 alternately conducts the switch elements Q11, Q14 and the switch elements Q12, Q13 which are arranged diagonally, and variably controls the ON pulse width thereof to control the output voltage. In FIG. 1, in order to generate an AC voltage between the node A and the node B from the current power source E, there are an operation mode to generate a positive voltage component of the AC voltage and an operation mode for generating a negative voltage component of the AC voltage.

Here, as an example, the operation of generating a negative voltage component of the AC voltage will be described.

### (First Operation Mode) Switch Elements Q12 and Q13: ON, Switch Elements Q11 and Q14: OFF

In the first operation mode, the current flows in an order of the power source E, the switch element Q13, the node B, the inductor 102, the node A, the switch element Q12 and the power source E. Consequently, the negative polarity energy is stored in the inductor 102.

### (Second Operation Mode) Switch Element Q11, Q13: ON, Switch Element Q12, Q14: OFF

In the second operation mode following the first operation mode, the current does not flow in the path of the first operation mode. However, the current flowing through the inductor 102 tries to keep continuity. That is, the inductor 102 attempts to continue flowing current from the node B to the node A. In this case, the current flows through the diode D11 coupled in anti-parallel with the switch element Q11. Therefore, when both the switch elements Q12 and Q14 are turned off, a current flows from the switch element Q13 which is turned on to the diode D11 in an order of the node B, the inductor 102 and the node A. Thus, in the second operation mode, commutation of the current occurs.

### (Third Operation Mode) Switch Elements Q12 and Q13: ON, Switch Elements Q11 and Q14: OFF

The third operation mode following the second operation mode is the same operation as the first operation mode. Therefore, the description is omitted.

### (Fourth Operation Mode) Switch Elements Q12, Q14: ON, Switch Elements Q11, Q13: OFF

In the fourth operation mode following the third operation mode, the current does not flow in the path of the third operation mode. However, the current flowing through the inductor 102 tries to keep continuity. That is, the inductor 102 attempts to continue flowing current from the node B to the node A. In this case, since a current does not flow from the switch element Q13 which is turned off to the node B, a current flows through the diode D14 which is coupled in anti-parallel with the switch element Q14. Therefore, when both the switch elements Q11 and Q13 are turned off, a current flows from the switch element Q12 to the node A in an order of the diode D14, the node B and the inductor 102. Thus, in the fourth operation mode, commutation of the current occurs.

Among the above operations, the first and third operation modes are referred to as a conduction mode, and the second and fourth operation modes are referred to as a commutation mode. The full-bridge inverter circuit 101 alternately repeats the conduction mode and commutation mode to produce an AC voltage.

### Circuit Configuration of First Embodiment

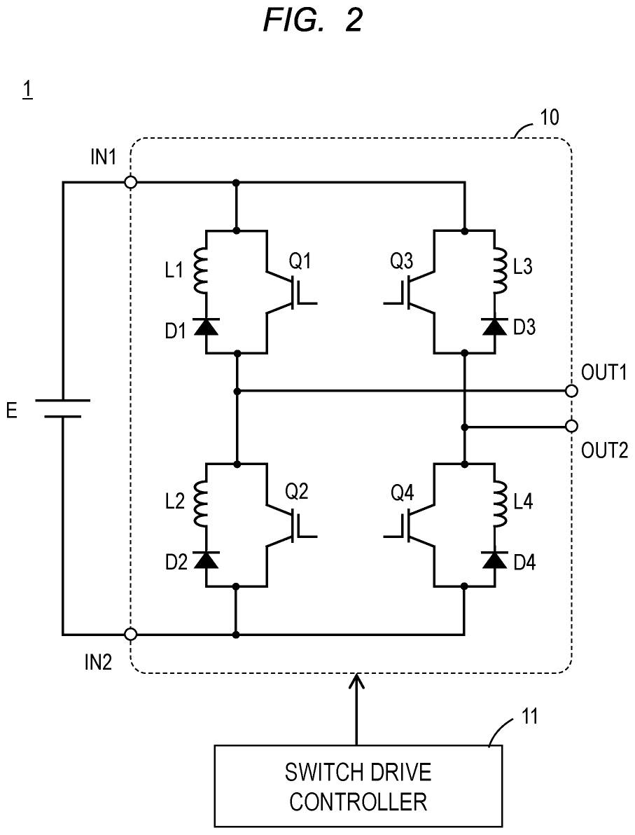

FIG. 2 is a diagram showing a configuration of an inverter device 1 according to first embodiment. The inverter device 1 includes a semiconductor device 10 having a full-bridge inverter circuit. The inverter device 1 includes a switch drive controller for driving a full-bridge inverter circuit included in semiconductor device 10. Incidentally, hereafter, semiconductor device 10 is referred to as a full-bridge inverter circuit 10.

The full-bridge inverter circuit 10 has an input terminal IN1 (first input terminal), an input terminal IN2 (second input terminal), an output terminal OUT1 (first output terminal) and an output terminal OUT2 (second output terminal). A DC power source E is coupled between the input terminal IN1 and IN2. Furthermore, the full-bridge inverter circuit 10 includes switch elements Q1-Q4, diodes D1-D4 and inductors L1-L4.

The switch elements Q1 and Q2 are coupled in series. A series circuit (first series circuit) including the switch elements Q1 and Q2 is coupled between the input terminals IN1 and IN2. That is, the series circuit including the switch device Q1 and Q2 is coupled in parallel to the DC power source E. The switch element Q1 is disposed on the high side (positive potential side), the switch element Q2 is disposed on the low side (negative potential side).

The switch elements Q3 and Q4 are coupled in series. A series circuit (second series circuit) including the switch elements Q3 and Q4 is coupled between the input terminals IN1 and IN2. That is, the series circuit including the switch device Q3 and Q4 is coupled in parallel to the DC power source E. The switch element Q3 is disposed on the high side (positive potential side), the switch element Q4 is disposed on the low side (negative potential side).

The joint of the switch elements Q1 and Q2 is electrically coupled to the output terminal OUT1. The joint of the switch elements Q3 and Q4 is electrically coupled to the output terminal OUT2. Between the output terminals OUT1 and OUT2, a load is coupled. Hereinafter, examples in which the inductor Lload is coupled as the load will be described.

A series circuit including a diode and an inductor is coupled in parallel to each of switch elements Q1 to Q4. Specifically, the series circuit (third series circuit) including the diode D1 and the inductor L1 is coupled in parallel to the switch element Q1. The series circuit (fourth series circuit) including the diode D2 and the inductor L2 is coupled in parallel to the switch element Q2. The series circuit (fifth series circuit) including the diode D3 and the inductor L3 is coupled in parallel to the switch element Q3. The series circuit (sixth series circuit) including the diode D4 and the inductor L4 is coupled in parallel to the switch element Q4.

The diodes D1 to D4 are respectively coupled to the switch elements Q1 to Q4 so that the forward current of the diode D1 to D4 flow in a direction opposite to a direction of the current flowing when the switch elements Q1 to Q4 are turned on, respectively. One end of each of the inductors L1 to L4 is coupled to the cathode of each diodes D1 to D4.

The switch elements Q1 to Q4 include, for example, field-effect transistors (FETs), MOSFET and IGBT (Insulated Gate Bipolar Transistor), and the like, but are not limited thereto.

### Operation of Inverter Device of First Embodiment

The operation of the inverter device 1 of first embodiment will be described. The full-bridge inverter circuit 10 according to first embodiment, similarly to a typical full-bridge inverter circuit, the switch elements Q1 and Q4 disposed diagonally, and the switch elements Q2 and Q3 are alternately conducted. The switch elements Q1 to Q4 are turned on or off by the PWM drive signals output from the switch drive controller 11. It is repeated alternately the conduction mode and the commutation mode according to the PWM drive signals, so that an AC voltage is generated between the output terminals OUT1 and OUT2. In FIG. 2, in order to generate an AC voltage between the output terminals OUT1 and OUT2 from a DC power source E, there are two operation modes which are an operation mode for generating a positive voltage component of an AC voltage and an operation mode for generating a negative voltage component of an AC voltage. Here, for example, the operation mode for generating a negative voltage component of the AC voltage.

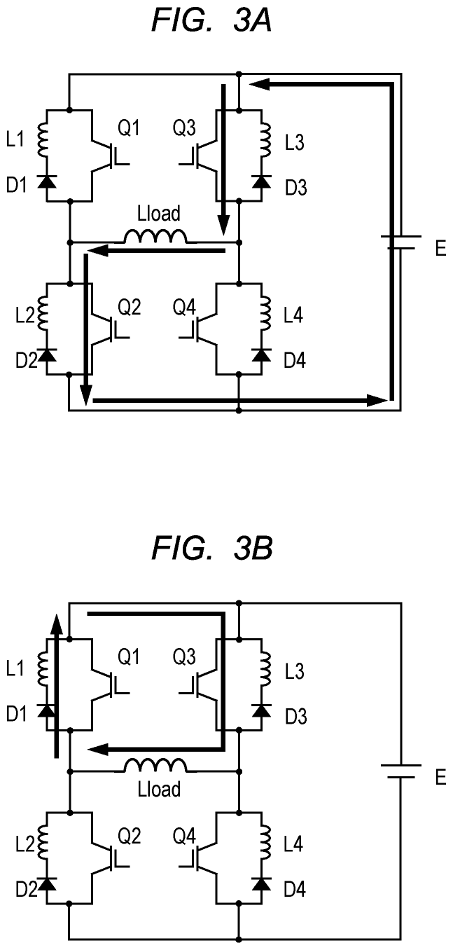

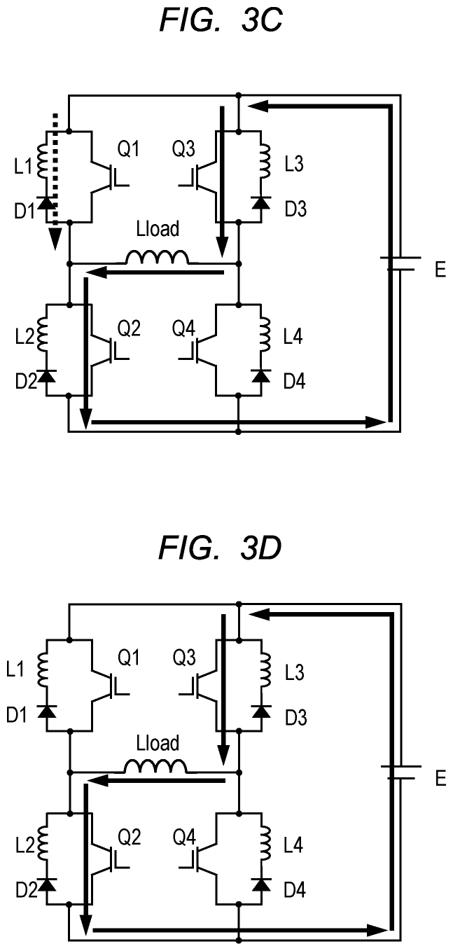

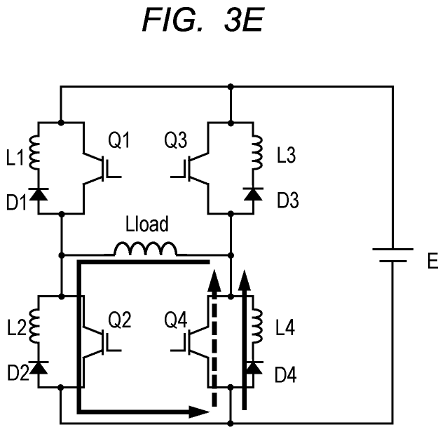

Referring to FIGS. 3A to 3E, the operation of the full-bridge inverter circuit 10 will be described. In FIGS. 3A to 3E, the input terminals IN1 and IN2 and the output terminals OUT1 and OUT2 are not shown.

### (First Operation Mode)

The first operation mode according to first embodiment shown in the FIG. 3A corresponds to the first operation mode (conduction mode) of typical full-bridge inverter device described above. That is, the switch elements Q2 and Q3 are turned on, the switch elements Q1 and Q4 are turned off. At this time, the current flows in an order of the power source E, the switch element Q3, the inductor Lload, the switch element Q2 and power supply E. Thus, energy is stored in the inductor Lload.

### (Second Operation Mode)

The second operation mode according to first embodiment shown in the FIG. 3B corresponds to the second operation mode (commutation mode) of typical full-bridge inverter device described above. That is, the switch elements Q1 and Q3 are turned on, the switch elements Q2 and Q4 are turned off. At this time, the current flowing through the inductor Lload as a load tries to keep continuity. Since the voltage applied across the switch element Q1 is small, no current flows through the switch element Q1. However, a current flows through a series circuit coupled in parallel with the switch element Q1. That is, a current flows through the series circuit including the diode D1 and the inductor L1. Therefore, a current flows in an order of the inductor Lload, the diode D1, the inductor L1 and switching device Q3. The full-bridge inverter circuit 10 is thus commutated.

### (Third Operation Mode)

The third operation mode according to first embodiment shown in FIGS. 3C and 3D is an operation mode subsequent to the second operation mode shown in FIG. 3B and corresponds to the third operation mode (conduction mode) of typical full-bridge inverter device described above. That is, the switch elements Q2, Q3 are turned on, the switch elements Q1, Q4 are turned off. In the third operation mode, the current flows in an order of the power source E, the switch element Q3, the inductor Lload, the switch element Q2 and the power source E.

Here, the switching loss with a transition from the second operation mode to the third operation mode, i.e., a transition from the commutation mode to the conduction mode will be described. FIG. 3C is a diagram schematically showing the flow of current immediately after transition from the second operation mode to the third operation mode. When the inverter device shifts from the second operation mode to the third operation mode, the switch element Q1 is turned from on to off, the switch element Q2 is turned from off to on. By the switch element Q1 is turned from on to off, the reverse recovery current flows through the diode D1. The reverse recovery current flows into the switch element Q2. Thus, the rise of the current flowing through the switch element Q2 is increased, and can cause an increase in switching loss. However, in first embodiment, the inductor L1 is inserted in series with the diode D1. By inserting the inductor L1, the rise of the current flowing into the switch element Q2 can be reduced. The reverse recovery current, i.e., the current flowing through the inductor L1 is represented (switching time)*(reverse voltage)/L1, it is possible to reduce the slope of the rise of the current.

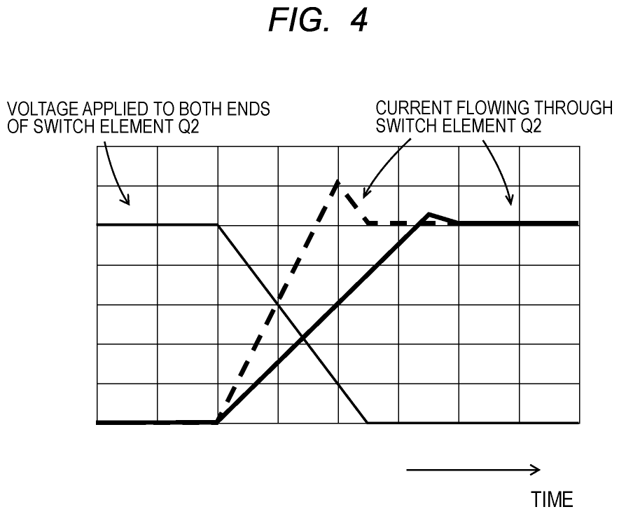

FIG. 4 shows the current flowing through the switch element Q2 and the voltage applied across the switch element Q2 when the switch element Q2 is turned from off to on. The dotted line shows the current flowing through the switch element Q2 when only the diode D1 is coupled in anti-parallel to the switch element Q1, the solid line shows the current flowing through the switch element Q2 according to first embodiment. The energy lost during the switching time depends on the product of the voltage and the current. In the configuration of present embodiment, since it is possible to reduce the rise of the current flowing into the switch element Q2, it is possible to reduce the switching loss by the switch elements.

FIG. 3D is a diagram schematically showing the flow of current after passing through the switching period in the third operation mode. After passing the switching period, the current flows in an order of the power source E, the switch element Q3, the inductor Lload, the switch element Q2 and the power source E, as shown in FIG. 3D.

### (Fourth Operation Mode)

The fourth operation mode according to first embodiment shown in FIG. 3E is an operation mode subsequent to the third operation mode shown in FIG. 3D, and corresponds to the fourth operation mode (commutation mode) of typical full-bridge inverter device described above. In the fourth operation mode, the switch elements Q2 and Q4 are turned on, and the switch elements Q1 and Q3 are turned off. After the transition to the fourth operation mode, since the voltage applied across the switch element Q4 is small, no current flows through the switch element Q4. However, in order to keep continuity of the current flowing through the inductor Lload as loads, the current flows through the series circuit coupled in parallel with the switching device Q4. That is, a current flows in an order of the inductor Lload, the switching device Q2, the diode D4, and the inductor L4.

Here, the switching loss with a transition from the third operation mode to the fourth operation mode, i.e., a transition from the conduction mode to the commutation mode will be described. When an inductor is inserted into a path through which current flows, such as present embodiment, the impedance is increased when transiting from the conduction mode to the commutation mode. However, in present embodiment, since the series circuit including the diode D4 and the inductor L4 is coupled in parallel to the switch element Q4, immediately after the series circuit transitions from the third operation mode to the fourth operation mode, a current flows first through the switch element Q4. Therefore, the voltage applied across the switch element Q4 does not increase greatly. As a result, the switching loss when the switch element Q3 is turned off can be as large as the switching loss when the switch element of the typical full-bridge inverter circuit 101 shown in FIG. 1.

As described above, according to present embodiment, the switching loss with the transition from the commutation mode to the conduction mode, i.e., when the switch element Q2 is turned from off to on, is reduced. On the other hand, the switching loss with the transition from the conduction mode to the commutation mode, i.e., when the switch element Q3 is turned from on to off, is comparable to the typical full-bridge inverter circuit. Therefore, according to present embodiment, overall, switching loss generated per pulse is reduced. The switching loss is proportional to the number of switching times. Therefore, for the inverter device with a higher switching frequency, it is expected to have a high switching loss reduction effect. Therefore, the full-bridge inverter circuit 10 according to present embodiment is suitable for the inverter device with a higher switching frequency.

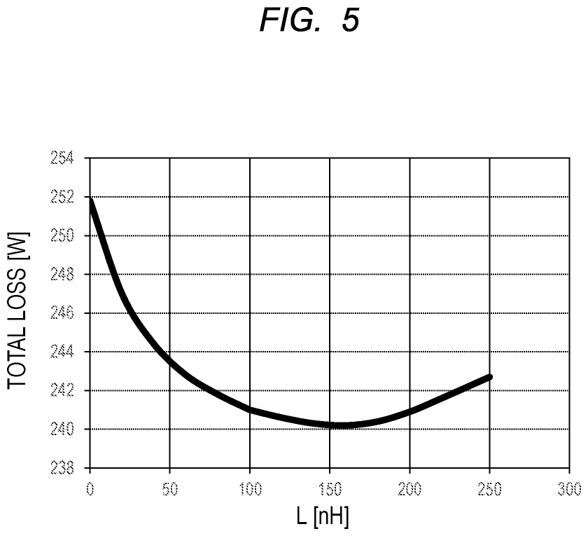

Incidentally, as described above, in order to reduce the switching loss of the full-bridge inverter circuit 10, it is necessary to appropriately determine the value of the inductor L. FIG. 5 is a result of simulation of the switching loss of the full-bridge inverter circuit 10 in which the total output is 10 kW. The vertical axis indicates the total loss of the full-bridge inverter circuit 10, the horizontal axis indicates the value of the inductor L1 to L4 to be inserted. It can be seen from FIG. 5 that the switching loss can be minimized, and the switching loss can be reduced by about 5% when the value of each of the inductors L1 to L4 of the full-bridge inverter circuit 10 is about 160 nH. Incidentally, it is needless to say that the optimum value of the inductors L1 to L4 is different in response to the circuit conditions such as the switch elements, diodes, the switching frequency and output.

In present embodiment, the full-bridge inverter circuit are explained. However, it is similarly applicable to the half-bridge inverter circuit. That is, by providing a series circuit made of a diode and an inductor coupled in parallel to the switch elements of the half-bridge inverter circuit, it is possible to reduce the switching loss of the half-bridge inverter circuit.

### Second Embodiment

Next, an inverter device including a HERIC inverter circuit (HERIC inverter device) will be described.

### Configuration of Typical HERIC Inverter Device

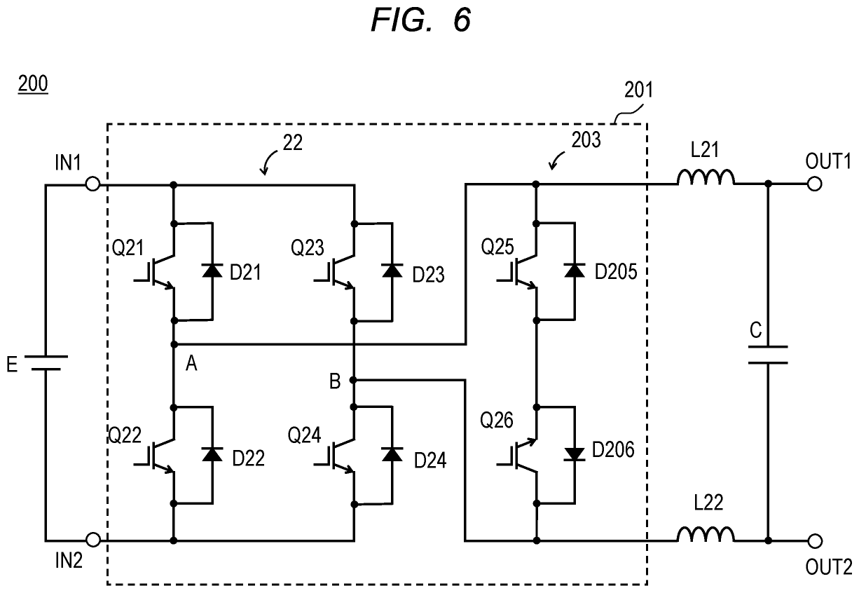

Before describing the present embodiment, a typical HERIC inverter device will be explained with reference to FIG. 6 in order to facilitate the understanding of the present embodiment. The HERIC inverter device 200 shown in FIG. 6 includes a HERIC inverter circuit 201, inductors L21 and L22, and a capacitor C.

The HERIC inverter circuit 201 includes a full-bridge inverter circuit 22 and a bidirectional circuit 203. The full-bridge inverter circuit 22 includes switch elements Q2 to Q24 and diodes D21 to D24. The configuration of the full-bridge inverter circuit 22 is the same as the configuration of the full-bridge inverter circuit 101 shown in FIG. 1, the description thereof is omitted.

The bidirectional circuit 203 includes switch elements Q25 and Q26. The switch elements Q25 and Q26 are coupled in series between nodes A and B. The switch element Q25 is coupled so as to flow or interrupt a current flowing from the node A to the node B. The switch element Q26 is coupled so as to flow or interrupt a current flowing from the node B to the node A. The diode D205 is coupled in anti-parallel to the switch element Q25. The diode D206 is coupled in anti-parallel to the switch element Q26.

One end of the inductor L21 is coupled to the node A. One end of the inductor L22 is coupled to the node B. The capacitor C is coupled between the other end of the inductor L21 and the other end of the inductor L22.

A DC power source E is coupled between the input terminals IN1 and IN2 of HERIC inverter device 200. Further, a load (not shown) is coupled between the output terminals OUT1 and OUT2 of HERIC inverter device 200 coupled between the other end of the inductor L21 and the other end of the inductor L22.

### Operation of Typical HERIC Inverter Device

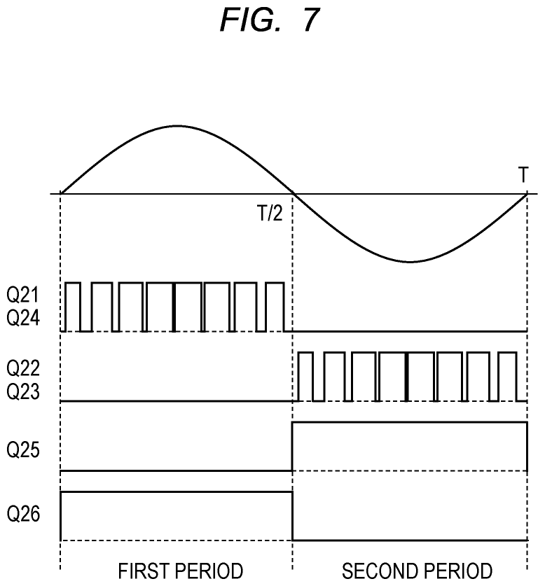

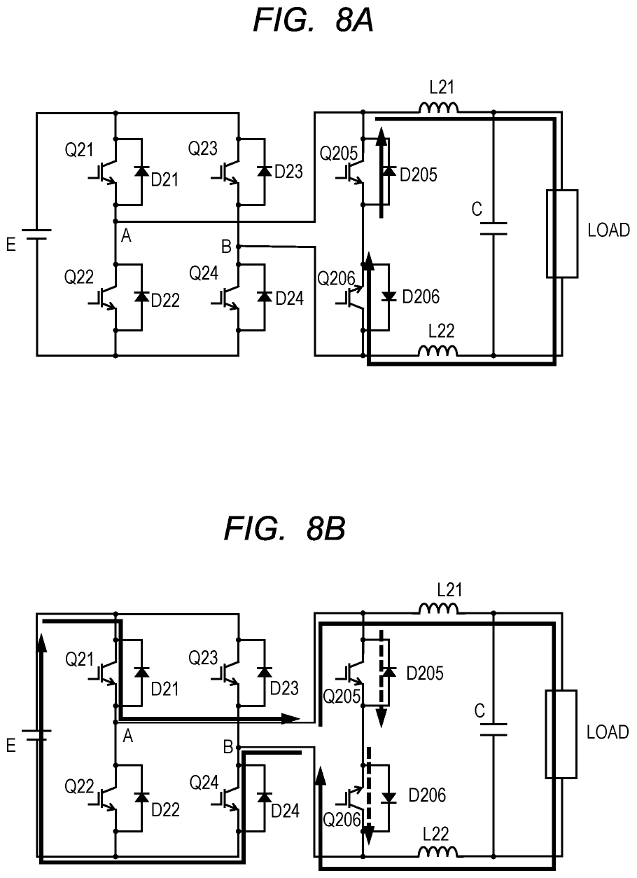

Referring to FIGS. 7, 8A and 8B, the operation of a typical HERIC inverter device will be explained. FIG. 7 is a diagram showing drive signals applied to the switch elements Q21 to Q26.

In first period, the switch elements Q21 and Q24 are controlled by the PWM drive signal. In the first period, the switch elements Q22, Q23, and Q25 are turned off, and the switch element Q26 is turned on. In the first period, while the switch elements Q21 and Q24 are turned on, the current flows in an order of the power source E, the switch element 21, node A, the inductor L21, load, the inductor L22, node B, the switch element Q24 and the power source E. While the switch elements Q21 and Q24 are turned off, the nodes A and B are in the vicinity of the intermediate potential of the power source E. Therefore, the diodes D21 to D24 are all reverse biased and no current flows. Thus, the path of current in the full-bridge circuit 22 is interrupted. Therefore, in the first period, as shown in FIG. 8A, the commutation current flows in an order of the inductor L21, load, the inductor L22, the switching device Q26 and the diode D205.

In the first period, when the switch elements Q21 and Q24 are turned from off to on, as shown in FIG. 8B, the reverse recovery current flows in the diode D205. Thus, the current flowing through the switch elements Q21 and Q24 is increased, as a result, so that the switching loss is increased.

In second period, as shown in FIG. 7, the switch elements Q22 and Q23 are controlled by the PWM drive signals, the switch elements Q21, Q24 and Q26 are turned off, the switch element Q25 is turned on. The operation in the second period is reversed from the operation in the first period. Therefore, when the switches Q22 and Q23 are turned off, similarly to the first period, no current flows through the diodes D21 to D24, and the commutation current flows in an order of the inductor L22, load, the inductor L21, the switch device Q25 and the diode D206 in the direction opposite to the first period.

In the second period, when the switch elements Q22 and Q23 are turned from off to on, as in the operation of the first period, the reverse recovery current flows in the diode D206. Thus, the current flowing through the switch elements Q22 and Q23 is increased, as a result, the switching loss is increased.

### Circuit Configuration of Second Embodiment

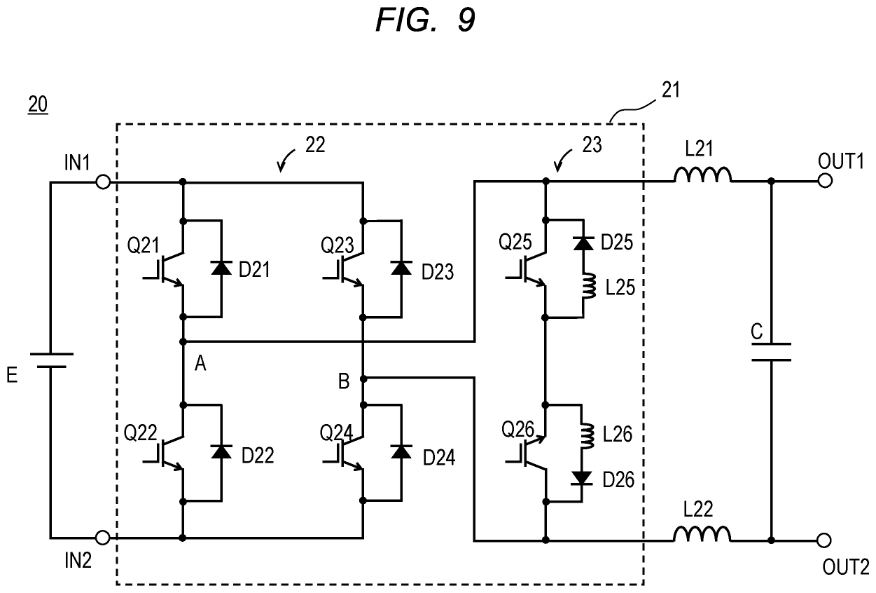

FIG. 9 shows HERIC inverter device 20 according to the second embodiment. The HERIC inverter device 20 includes a semiconductor device 21 with HERIC inverter circuit, inductors L21 and L22, and a capacitor C. Furthermore, HERIC inverter device 20 includes a switch drive controller (not shown) for controlling HERIC inverter circuit. Incidentally, hereafter, the semiconductor device 21 is referred to as HERIC inverter circuit 21.

The HERIC inverter circuit 21 includes a full-bridge inverter circuit 22 and the bidirectional circuit 23. The configuration of the full-bridge inverter circuit 22 may be similar to that shown in FIG. 6. In addition, components having the same functions as those shown in FIG. 6 except for the full bridge circuit are denoted by the same reference numerals, and descriptions thereof are omitted.

The bidirectional circuit 23 shown in FIG. 9, switch elements Q25 and Q26 coupled in series between the node A and the node B, series circuits respectively coupled in anti-parallel to the switch elements Q25 and Q26. The series circuits each include a diode and an inductor. Specifically, a series circuit including the diode D25 and the inductor L25 is coupled in parallel to the switch element Q25. A series circuit including the diode D26 and the inductor L26 is coupled in parallel to the switch element Q26. The inductors L25 and L26 are respectively coupled to the cathodes of diodes D25 and D26.

### Operations of HERIC Inverter Device of Second Embodiment

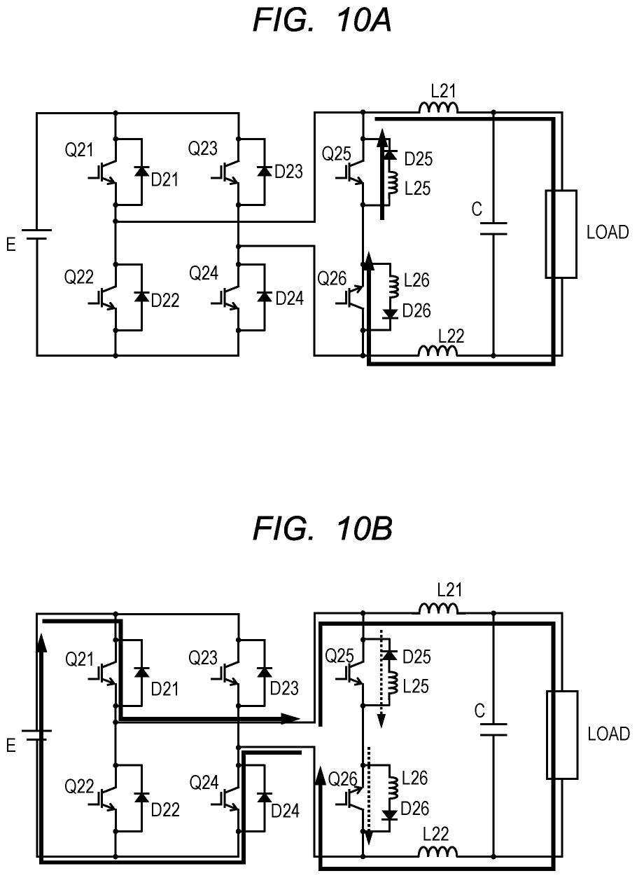

Next, the operation of HERIC inverter device according to second embodiment will be described with reference to FIGS. 10A and 10B. Each of the switch elements Q21 to Q26 is provided with a drive signal as shown in FIG. 7.

In first period, the switch elements Q21 and Q24 are controlled by the PWM drive signals. In first period, the current path flowing while the switch elements Q21 and Q24 are turned on, and the current path flowing while the switch elements Q21 and Q24 are turned off are the same as the typical HERIC inverter device 200 as described above, the description thereof will be omitted. FIG. 10A shows a current path that flows while the switch elements Q21 and Q24 are turned off in present embodiment.

Also, in the HERIC inverter device 20 of present embodiment, when the switch elements Q21 and Q24 are turned from off to on, a reverse recovery current flows in the diode D25, as shown in FIG. 10B. Thus, the current flowing through the switch elements Q21 and Q24 is increased. However, in present embodiment, since the inductor L25 is inserted into the path through which the reverse recovery current flows, it is possible to reduce the slope of the current increase due to the reverse recovery current. As a result, it is possible to suppress an increase in switching loss when the switch elements Q21 and Q24 are turned on.

In the second period, the switching loss when the switch elements Q22 and Q23 are turned from off to on can also be suppressed as well as the switching loss in the first period.

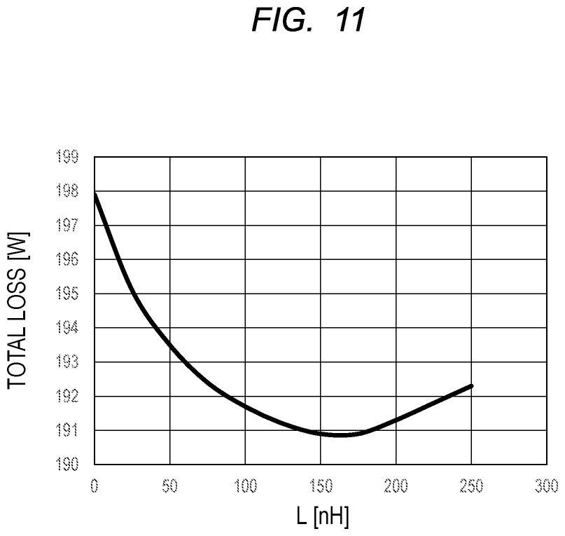

As described above, in order to improve the switching loss of the HERIC inverter circuit 21, the values of the inductors L25 and L26 need to be appropriately obtained. FIG. 11 shows a result obtained by simulating the switching loss of the HERIC inverter circuit 21 in which the total output is 10 kW. The vertical axis indicates the total loss of HERIC inverter circuit 21, the horizontal axis indicates the value of the inductors L1 to L4 to be inserted. As shown in FIG. 11, switching loss can be minimized by setting the values of the inductors L25 and L26 in the HERIC inverter circuits 21 to approximately 160 nH. As a result, it is understood that the switching loss can be improved by about 4%. Incidentally, it is needless to say that the optimum value of the inductor L25 and L26 is different in response to the circuit conditions such as the switch elements, the diodes, the switching frequency and output.

Although the invention made by the present inventor has been specifically described based on the embodiment, the present invention is not limited to the embodiment described above, and it is needless to say that various modifications can be made without departing from the gist thereof.

1. A semiconductor device comprising:
a first and a second input terminal;
a first series circuit having a plurality of switch elements coupled between the first and the second input terminal; and
a plurality of second series circuits, each having a diode and an inductor and being coupled in parallel to a corresponding one of the switch elements,
wherein values of the inductors of the second series circuits are equal.

2. The semiconductor device according to claim 1,
wherein the diode is coupled to the corresponding one of the switch elements to flow a forward current in a direction opposite to a direction of a current flowing through the corresponding one of the switch elements turned on, and
wherein the inductor is coupled to a cathode of the diode.

3. The semiconductor device according to claim 1, wherein each of the switch elements is an IGBT.

4. The semiconductor device according to claim 1, wherein each of the switch elements is a MOSFET.

5. The semiconductor device according to claim 1, wherein the switch elements and the second series circuits configure a full-bridge inverter circuit.

6. An inverter device comprising:
the semiconductor device according to claim 1; and
a switch drive controller driving the switch elements.

7. The semiconductor device according to claim 1, wherein the first input terminal and the second input terminal are provided for coupling a DC power source therebetween.

8. An inverter device comprising:
a first and a second input terminal for coupling a DC power supply source therebetween;
a first series circuit having a first switch element and a second switch element which are coupled between the first input terminal and the second input terminal;
a second series circuit having a third switch element and a fourth switch element which are coupled between the first input terminal and the second input terminal;
a third series circuit having a first diode and a first inductor and coupled in parallel to the first switch element;
a fourth series circuit having a second diode and a second inductor and coupled in parallel to the second switch element;
a fifth series circuit having a third diode and a third inductor and coupled in parallel to the third switch element;
a sixth series circuit having a fourth diode and a fourth inductor and coupled in parallel to the fourth element;
a first output terminal electrically coupled to a joint of the first switch element and the second switch element;
a second output terminal electrically coupled to a joint of the third switch element and the fourth switch element; and
a switch drive controller configured to drive the first, the second, the third and the fourth switch element,
wherein values of the first to the fourth inductor are the same.

9. The inverter device according to claim 8,
wherein the first diode is coupled to the first switch element to flow a forward current in a direction opposite to a direction of a current flowing through the first switch element turned on,
wherein the first inductor is coupled to a cathode of the first diode,
wherein the second diode is coupled to the first switch element to flow a forward current in a direction opposite to a direction of a current flowing through the second switch element turned on,
wherein the second inductor is coupled to a cathode of the second diode,
wherein the third diode is coupled to the third switch element to flow a forward current in a direction opposite to a direction of a current flowing through the third switch element turned on,
wherein the third inductor is coupled to a cathode of the third diode,
wherein the fourth diode is coupled to the fourth switch element to flow a forward current in a direction opposite to a direction of a current flowing through the fourth switch element turned on, and
wherein the fourth inductor is coupled to a cathode of the fourth diode.

10. A semiconductor device comprising:
a first series circuit having a first and a second switch element and coupled in parallel to a DC power source;
a second series circuit having a third and a fourth switch element and coupled in parallel to the DC power source;
a first, a second, a third and a fourth diode respectively coupled parallel in to the first, the second, the third and the fourth switch element;
a third series circuit having a fifth and a sixth switch element and coupled between a first node and a second node, the first node being a joint of the first and the second switch element, the second node being a joint of the third and the fourth switch element;
a fourth series circuit having a fifth diode and a first inductor and coupled in parallel to the fifth switch element; and
a fifth series circuit having a sixth diode and a second inductor and coupled in parallel to the sixth switch element,
wherein a value of the first inductor is equal to a value of the second inductor.

11. The semiconductor device according to claim 10,
wherein the fifth diode is coupled to the fifth switch element to flow a forward current in a direction opposite to a direction of a current flowing through the fifth switch element turned on,
wherein the first inductor is coupled to a cathode of the fifth diode,
wherein the sixth diode is coupled to the sixth switch element to flow a forward current in a direction opposite to a direction of a current flowing through the sixth switch element turned on,
wherein the second inductor is coupled to a cathode of the sixth diode, and
wherein the direction of the current flowing through the fifth switch element turned on is different from the direction of the current flowing through the sixth switch element turned on.

12. A inverter device comprising:
the semiconductor device according to claim 10;
a third inductor having a first end and a second end, the first end being coupled to the first node;
a fourth inductor having a third end and a fourth end, the third end being coupled to the second node; and
a capacitor coupled between the second end and the fourth end.

13. The semiconductor device according to claim 10,
wherein the fifth switch element is coupled to the first node and provided to flow a current from the first node to the second node, and
wherein the sixth switch element is coupled to the second node and provided to flow a current from the second node to first node.
